(19) United States
(12) Patent Application Publication
(10) Pub. No.: US 2012/0067399 A1
(43) Pub. Date: Mar. 22, 2012

(54) PHOTOVOLTAIC MODULE WITH CERAMIC COATING HEAT RADIATING SHEET

(76) Inventors: Chung Kwon Park, Busan (KR); Gyu Hwan Jang, Busan (KR)

(21) Appl. No.: 13/139,465

(22) PCT Filed: May 7, 2010
(86) PCT No.: PCT/KR2010/002910

§ 371 Date: Jun. 13, 2011

(30) Foreign Application Priority Data
Jun. 11, 2009 (KR) 10-2009-0052067

(51) Int. Cl. H01L 31/024; H01L 31/052

(52) U.S. Cl. 136/246

(57) ABSTRACT

The present invention relates to a photovoltaic module characterized by comprising a heat radiating sheet overlaid with a ceramic coating layer, which is attached to a conventional photovoltaic module. In a method of increasing heat radiation with the aid of the ceramic coating layer provided on both sides or one side of the heat radiating sheet, heat generated by a solar cell due to the differences in thermal emissivity, thermal shear rate and surface area of a material is transferred to a solar EVA and then a heat radiating sheet thin plate that serves as a carrier, and returns back to the ceramic coating layer for emission. A high thermal emissivity is obtained by having a so-called heat transfer phenomenon in one direction, which resultantly improves a heat radiation performance and increases the refrigeration efficiency of the photovoltaic module and its peripheral devices to thus lower the internal temperature. As such, the power generation rate and efficiency through a module to which the heat radiating sheet is applied can be maximized, and a photovoltaic module with such a heat radiating sheet can maintain a change in the power generation rate traditionally due to a change in the surface temperature at a constant level, thereby increasing the annual power generation rate by 3-5% compared to that of the conventional one and improving the power generation effect during the summer season by 5-10%. Further, wide applicability can be ensured by equally applying the photovoltaic module of the present invention to areas having severe heat or high-temperature and high-humidity tropical weather as well as desert areas. In addition, the photovoltaic module according to the present invention is advantageous in that it is applicable not only to a new module but also to an already existing module, which makes it possible to manufacture those photovoltaic modules under the same process conditions as with the conventional ones without modifying the existing equipment.

### TECHNICAL FIELD

The present invention relates to a photovoltaic module in which a heat-dissipating sheet having a ceramic coating layer formed thereon is attached to an existing photovoltaic module, and more particularly, to such a photovoltaic module in which the photovoltaic module and peripheral devices thereof is cooled by using the heat-dissipating properties improved by a ceramic coating layer formed on the outer surface of a heat-dissipating sheet, thereby maximizing the amount of electricity generated from solar and improving the durability of the photovoltaic module through the ceramic coating layer.

### BACKGROUND ART

In general, it is known that photovoltaic power generation is relatively high in electricity generation efficiency in an area where solar irradiation is high. A photovoltaic power generation facility is currently being built in a photovoltaic power generation business area while being closely associated with the solar irradiation.

In case of a typical photovoltaic power generation facility, the amount of electricity generated from solar must be increased in the season when the solar irradiation is the highest. However, actually, as shown in FIG. 1, the average amount of electricity generated from solar is higher in April and November when the solar irradiation is low but the ambient temperature is cool than in June when the solar irradiation is the highest. Also, in the case where the surface of the photovoltaic module is maintained at a high temperature ranging from about 60 to 80° C. in August when the ambient temperature is the highest, the average efficiency of electricity generation from solar drops to a level of 12%. That is, as generally well-known, it can be seen from such a fact that the amount or efficiency of electricity generation depending on the surface temperature of the photovoltaic module is not greatly affected by a single crystalline polysilicon or poly-crystalline silicon photovoltaic module, and the heat generated from the photovoltaic module itself and peripheral devices thereof has a significant effect on the amount of electricity generated from solar.

It can also be seen from the above fact that there is a difference in the efficiency of electricity generation in the range from about 5 to 10% as shown in the amount of electricity generation from solar by season in FIG. 1. In addition, a generally known thin film photovoltaic module shows a difference in the efficiency of electricity generation of more than about 5% according to a variation in the surface temperature thereof, which is disclosed in general documents. It can be seen from the above result that in case of both a single 173 W module and a poly 181 W module, the amount of electricity generated from solar is increased as the temperature is lowered as shown in FIG. 2. That is, it can be seen that as the temperature is low according to a variation in the module and ambient temperature under the same solar irradiation conditions, the amount of electricity generation is increased. Generally, unlike the expectation that the efficiency of electricity generation from solar will also be the highest during the summer time when the solar irradiation is the highest, the photovoltaic module shows a substantially low electricity generation efficiency by the surface temperature thereof. Such a phenomenon also occurs in the thin film photovoltaic module as well as the poly-crystalline or single crystalline silicon photovoltaic module in the same manner.

As described above, the amount of electricity generated from solar is greatly affected by a variation in the temperature of the photovoltaic module and peripheral devices thereof. However, since a typical photovoltaic module has a structure of including a glass substrate 10, a front side solar EVE film 20, solar cells 30, a back side solar EVA film 40, and a back sheet 50 and employs an EVA polymeric material as shown in FIG. 3, the heat generated from the photovoltaic module itself and the low heat-dissipating effect of peripheral devices thereof are the greatest obstacle to the photovoltaic power generation.

In the meantime, as solutions to the above problem, various technologies are developed and are filed as patents. As a representative patent, Korean Patent Registration No. 10-0867655 discloses a photovoltaic module for roof panel in which a solar cell plate 120 and a glass plate 130 are mounted on a top of a main body 110, and a heat insulation material 160 is filled in a space defined between the solar cell plate 120 and a bottom of the main body 110 as shown in FIG. 4. In such a photovoltaic module as structured above, the glass plate 130 serves as a protective cover which protectively covers the solar cell plate 120 to prevent the solar cell plate from being contaminated or damaged. A heat-absorbing plate 170 is configured to receive heat generated from the solar cell plate 120 and cool the solar cell plate 120 through cooling fluid flowing in a cooling pipe 150 to effectively prevent the overheating of the solar cell 120. However, the above photovoltaic module entails problems in that the cooling pipe 150 through which the cooling fluid flows is embedded in the photovoltaic module, so that the weight of the module is increased, which results in limited installation space of the module as well as complicated the structure of the module, thus making it difficult to manufacture the module. In addition, the conventional photovoltaic module encounters a problem in that a separate place is required to install a tank for storing the cooling fluid.

Besides, as a technology having a simple structure which compensates the above problems, Korean Patent Laid-Open Publication No. 2005-0094179 discloses a photovoltaic module which includes a reinforced glass plate 121, a solar cell 123 embedded in an EVA resin film 122, and a heat-conducting plate 124 mounted on a bottom of the EVA resin film 122 for absorbing heat generated from the solar cell 123 inside the module and dissipating the heat to the outside as shown in FIG. 5. Such a photovoltaic module, however, involves a problem in that as the heat-conducting plate 124 having a heat-dissipating function employs aluminum, copper, tin, stainless steel, etc., in the case where a predetermined period of time has elapsed in high-temperature high-humidity climate zones such as ocean shores, riverside lakes, or the like, a corrosion phenomenon occurs even inside a metal material of the heating-conducting plate adhered to the photovoltaic module, thereby leading to a deterioration of the heat-dissipating function and the durability of the heating-conducting plate.

This typical photovoltaic module is composed of materials having a high moisture resistance. The reason for this is that since a crystalline polysilicon is significantly susceptible to moisture, the crystalline polysilicon is changed to silica due to the blushing phenomenon occurring upon the contact of the crystalline polysilicon with moisture, thereby losting the function itself of the photovoltaic module. In addition, even in the case where the photovoltaic module includes a metal material sheet having the heat-dissipating function, the corrosion easily occurs even inside a metal material due to moisture in high-temperature high-humidity climate zones. Therefore, there is an urgent need for a countermeasure for ensuring high durability and long lifespan of more than 20 years when the photovoltaic module is installed once.

### DISCLOSURE OF INVENTION

### Technical Problem

The present invention is intended to maximize the efficiency of electricity generation of a photovoltaic module by cooling the photovoltaic module and peripheral devices thereof and lowering the temperature of the inside of the photovoltaic module through the heat-dissipating function of a heat-dissipating sheet having a ceramic coating layer formed thereon.

Accordingly, an object of the present invention is to provide a photovoltaic module including a heat-dissipating sheet, in which the heat-dissipating sheet having a ceramic coating layer formed thereon is bonded to the outer surface of a back sheet of an existing photovoltaic module using a pressure sensitive adhesive pressure-sensitive adhesive double-coated tape tape or an adhesive having the heat resistant and heat-conducting functions, so that the ceramic coating layer is in excellent in the heat-dissipating effect to increase the efficiency of electricity generation from solar, corrosion of the module is prevented by the ceramic coating layer of the heat-dissipating sheet to improve durability of the module, and it is possible to manufacture the module using only an existing basic equipment and process without any necessity of an additional facility.

Another object of the present invention is to provide a photovoltaic module including a heat-dissipating sheet, in which a back sheet is removed from the existing photovoltaic module and a heat-dissipating sheet having a ceramic coating layer formed thereon is directly attached to a back side solar EVA film unlike the photovoltaic module having the above limited structure, so that the temperature of the inside of the photovoltaic module is lowered by the heat-dissipating effect of the heat-dissipating sheet to maximize the efficiency of the electricity generation of the existing photovoltaic module, corrosion of the module is prevented by the ceramic coating layer of the heat-dissipating sheet to improve durability of the module, and the structure of the module is simplified to reduce the manufacturing cost of the module.

As such, the present invention is characterized in that the ceramic coating layer is formed on either both sides of the heat-dissipating sheet or a side opposite to a side of the heat-dissipating sheet abutting against the back side solar EVA film or the back sheet, so that heat generated from a solar cell due to the differences in thermal emissivity, thermal shear rate and surface area of a material is transferred to a solar EVA film and then a heat-dissipating sheet thin plate serving as a carrier, and reaches the ceramic coating layer for emission, thereby resulting in an increase in heat dissipating efficiency. In addition, a high thermal emissivity is obtained by allowing a so-called heat transfer phenomenon to occur in one direction, which resultantly improves a heat dissipation performance and increases the cooling efficiency of the photovoltaic module and its peripheral devices to thus lower the internal temperature. As such, the amount and efficiency of electricity generation through the module to which the heat-dissipating sheet is applied can be maximized and the physical properties such as durability, corrosion resistance, moisture resistance, etc., of the heat-dissipating sheet can be improved by the ceramic coating layer, resulting in the extended lifespan of the photovoltaic module.

### Technical Solution

The present invention is intended to maximize the efficiency of electricity generation of a photovoltaic module by cooling the photovoltaic module and peripheral devices thereof and lowering the temperature of the inside of the photovoltaic module through the heat-dissipating function of a heat-dissipating sheet having a ceramic coating layer formed thereon.

To achieve the above objects, in one aspect, the present invention provides a photovoltaic module including a heat-dissipating sheet having a ceramic coating layer, the module including a glass substrate 10, a front side solar EVA film 20, solar cells 30, a back side solar EVA film 40, and a back sheet 50, which are sequentially laminated in this order, wherein the heat-dissipating sheet 60 having the ceramic coating layer formed thereon is attached to the outer surface of the back sheet 50 using a pressure sensitive adhesive pressure-sensitive adhesive double-coated tape tape or adhesive 55.

In another aspect, the present invention provides a photovoltaic module including a heat-dissipating sheet having a ceramic coating layer, the module including a glass substrate 10, a front side solar EVA film 20, solar cells 30, a back side solar EVA film 40, and the heat-dissipating sheet 60 having the ceramic coating layer formed thereon, which are sequentially laminated in this order.

In the photovoltaic module of the present invention, preferably, the heat-dissipating sheet 60 uses any one selected from thin metal sheets having an emissivity equal to or more than that of aluminum, copper, brass, sheet steel, stainless steel, and similar materials, which are excellent in heat conductivity.

In addition, the ceramic coating layer is formed on either one side or both sides of the heat-dissipating sheet through a typical ceramic coating method to form a heat conductive ceramic coating layer.

### Advantageous Effects

The photovoltaic module of the present invention implements a structure in which a heat-dissipating sheet formed with a ceramic coating layer is attached thereto through an improvement of an existing photovoltaic module. The inventive photovoltaic module has advantageous effects in that the ceramic coating layer is formed on a side opposite to a side of the heat-dissipating sheet abutting against the back sheet, so that heat generated from a solar cell due to the differences in thermal emissivity, thermal shear rate and surface area of a material is transferred to a solar EVA film and then a heat-dissipating sheet thin plate serving as a carrier, and reaches the ceramic coating layer for emission, thereby resulting in an increase in heat dissipating efficiency. In addition, a high thermal emissivity is obtained by allowing a so-called heat transfer phenomenon to occur in one direction, which resultantly improves a heat dissipation performance and increases the cooling efficiency of the photovoltaic module and its peripheral devices to thus lower the internal temperature. As such, the amount and efficiency of electricity generation through the module to which the heat-dissipating sheet is applied can be maximized. In addition, as the heat-dissipating sheet is applied to the photovoltaic module, a change in the amount of electricity generation can be maintained at a constant level irrespective of a variation in the surface temperature of the conventional photovoltaic module, thus increasing the amount of electricity generation by 3 to 5% annually and 5 to 10% during the summer time. Further, the photovoltaic module of the present invention has the advantages of being able to be variously applied to an extremely hot or high-temperature high-humidity tropical climate zone, or to a desert zone.

In addition, the photovoltaic module according to the present invention can be applied not only to new modules but also to modules which have already been produced, and can be manufactured without changing the existing facility under the same process conditions as the existing process conditions.

### BRIEF DESCRIPTION OF THE DRAWINGS

The present invention is intended to maximize the efficiency of electricity generation of a photovoltaic module by cooling the photovoltaic module and peripheral devices thereof and lowering the temperature of the inside of the photovoltaic module through the heat-dissipating function of a heat-dissipating sheet having a ceramic coating layer formed thereon.

FIG. 1 is a graph illustrating the amount of electricity generated from solar according to monthly solar irradiation by a typical photovoltaic module.

FIG. 2 is a graph illustrating a relationship between a temperature and a maximum power Pmax;

FIG. 3 is a cross-sectional view illustrating the structure of a typical photovoltaic module.

FIG. 4 is a cross-sectional view illustrating one example of the structure of a conventional photovoltaic module.

FIG. 5 is a cross-sectional view illustrating another example of the structure of a conventional photovoltaic module.

FIG. 6 is a cross-sectional view illustrating the structure of a photovoltaic module in which a heat-dissipating sheet is bonded to a back sheet using a pressure sensitive adhesive pressure-sensitive adhesive double-coated tape tape according to one embodiment of the present invention.

FIG. 7 is a cross-sectional view illustrating the structure of a photovoltaic module in which a heat-dissipating sheet is bonded to a back side solar EVA film with a back sheet removed from the module according to another embodiment of the present invention.

FIG. 8 is a photograph illustrating a facility for measuring the heat-dissipating effect of the photovoltaic module.

FIG. 9 is a graph illustrating the measured average values of changes in the surface temperature of a conventional photovoltaic module including a heat-dissipating sheet, and an attachable type module and a replaceable type module, which have a ceramic coating layer formed thereon.

FIG. 10 is a graph illustrating the efficiency of the amount of electricity generation according to the heat-dissipating effect of a photovoltaic module according to the present invention on a monthly basis.

### BEST MODE FOR CARRYING OUT THE INVENTION

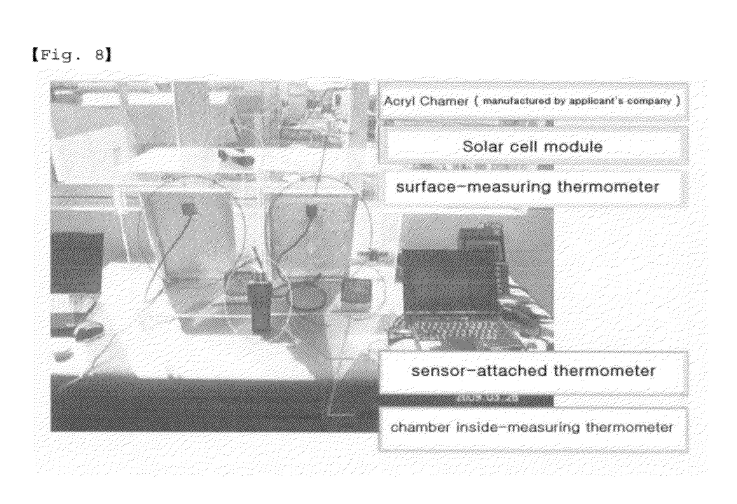

Now, the preferred embodiments of the present invention will be described hereinafter in more detail with reference to FIGS. 6 to 9. In the meantime, in the detailed description and the accompanying drawings, the detailed description on either the construction which can be easily understood by those skilled in the art associated with the photovoltaic power generation industry or the elements and their operation which are not directly related with the technical characteristics of the present invention will be omitted.

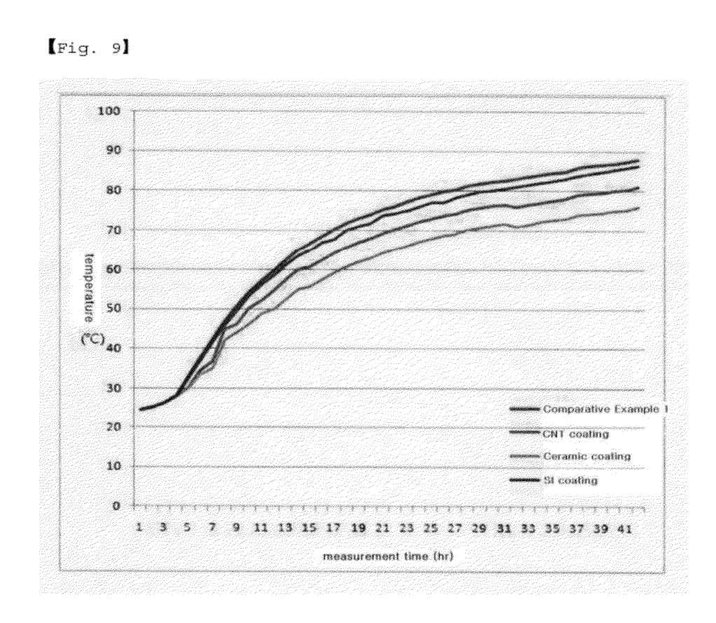

FIG. 6 is a cross-sectional view illustrating the structure of a photovoltaic module in which a heat-dissipating sheet is bonded to a back sheet using a pressure sensitive adhesive pressure-sensitive adhesive double-coated tape tape according to one embodiment of the present invention, and FIG. 7 is a cross-sectional view illustrating the structure of a photovoltaic module in which a heat-dissipating sheet is bonded to a back side solar EVA film with a back sheet removed from the module according to another embodiment of the present invention.

As shown in FIG. 6, a photovoltaic module (also, hereinafter referred to as “attachable type module”) including a heat-dissipating sheet having a ceramic coating layer according to one embodiment of the present invention is structured such that it includes a glass substrate 10, a front side solar EVA film 20, solar cells 30, a back side solar EVA film 40, and a back sheet 50, which are sequentially laminated in this order. A heat-dissipating sheet 60 having a ceramic coating layer formed thereon is attached to the outer surface of the back sheet 50 using a pressure sensitive adhesive pressure-sensitive adhesive double-coated tape tape or adhesive 55.

A typical conventional photovoltaic module as shown in FIG. 3 includes a glass substrate 10, a front side solar EVA film 20, solar cells 30, a back side solar EVA film 40, and a back sheet 50, which are laminated sequentially in this order. The back sheet 50 made of a fluorocarbon resin material serves to deteriorate a heat-dissipating or heat transfer function.

In addition, since the production process of an existing photovoltaic module employs a heat bonding method in which respective materials are vacuum-pressed at a time, it is not easy to change the process or the materials.

Thus, the attachable type module according to the present invention is characterized by a simple structure which enables a photovoltaic module having a heat-dissipating function to be easily manufactured even through a simple process of bonding a thin film type heat-dissipating sheet to a final product of the photovoltaic module.

Further, the attachable type module is constructed such that a heat-dissipating sheet is directly attached to the outer surface of the back sheet 50 made of a fluorocarbon resin material using a pressure sensitive adhesive pressure-sensitive adhesive double-coated tape tape or adhesive having a heat resistant and heat-conducting function so that the heat accumulated on the back sheet is transferred to the heat-dissipating sheet through the pressure-sensitive adhesive double-coated tape tape or the adhesive layer to dissipate the heat to the outside to cool the photovoltaic module and peripheral devices thereof.

The pressure sensitive adhesive pressure-sensitive adhesive double-coated tape tape which can be used in the present invention is a pressure sensitive adhesive pressure-sensitive adhesive double-coated tape tape having a heat resistant and heat-conducting function. All the typical pressure sensitive adhesive pressure-sensitive adhesive double-coated tape tape which is currently put on the market can be applied to the photovoltaic module. In addition, any adhesive can be applied to the photovoltaic module as long as it has the heat resistant and heat-conducting function.

Concrete examples of the pressure sensitive adhesive pressure-sensitive adhesive double-coated tape tape having a heat resistant and heat-conducting function preferably include pressure sensitive adhesive pressure-sensitive adhesive double-coated tape tapes, which are manufactured by 3M or Two-Hands Industry. Besides such types of pressure sensitive adhesive pressure-sensitive adhesive double-coated tape tapes, all kinds of the tapes can be applied to the photovoltaic module of the present invention as long as they have the physical properties that are equal or more than the heat resistant and heat-conducting property.

In addition, concrete examples of the adhesive having a heat resistant and heat-conducting function preferably include a ceramic (metal) adhesive manufactured by 3M, a heat resistant silicon adhesive and an epoxy adhesive manufactured by Dow Corning Corporation, heat resistant silicon adhesives manufactured by other companies, and the like. Besides such types of adhesives, all kinds of the adhesives can be applied to the photovoltaic module of the present invention as long as they have the physical properties that are equal or more than the heat resistant and heat-conducting property.

In the attachable type module according to the present invention as structured above, it could be found from the experiments that the heat-dissipating sheet is attached to the outer surface of the back sheet so that the ambient temperature of the photovoltaic module drops to a maximum of 10° C. or so as compared to the ambient temperature of the conventional photovoltaic module.

In a situation where the back sheet attached photovoltaic module according to the present invention faces intense price competition in a recent photovoltaic module industry market, the manufacturing cost of the heat-dissipating sheet using the adhesive is higher than that of the existing photovoltaic module. Thus, it is preferable to limitedly apply the heat-dissipating sheet to only a premium product of 220 W level.

In addition, as shown in FIG. 7, a photovoltaic module (also, hereinafter referred to as “replaceable sheet type module”) including a heat-dissipating sheet having a ceramic coating layer according to one embodiment of the present invention is structured such that it includes a glass substrate 10, a front side solar EVA film 20, solar cells 30, a back side solar EVA film 40, and the heat-dissipating sheet 60 having the ceramic coating layer formed thereon, which are sequentially laminated in this order.

The replaceable sheet type module has the above structure is constructed such that the existing back sheet 50 is removed from the typical photovoltaic module and the back sheet 50 is replaced with the heat-dissipating sheet 60 as shown in FIG. 7. Such a replaceable sheet type module is characterized in that all the works are performed in the basic equipment and process for manufacture for the existing photovoltaic module to eliminate the necessity of an additional facility so that the work process time is shortened to achieve the price competition and the process improvement at the same time, and furthermore an existing polymeric back sheet 50 is removed from the module so that the module can be improved to smoothly perform a heat-dissipating function.

The above replaceable type module has a heat-dissipating effect of 10□ or so unlike the existing photovoltaic module, but has a heat-dissipating effect which is one and a half times higher than the attachable type module so that the surface temperature of the photovoltaic module is lowered by more than about 15□.

The heat-dissipating effect as described above is a result obtained by applying only the heat-dissipating sheet to a pure photovoltaic module without taking the heat transfer efficiency of the back side solar EVA film into consideration.

In addition, in the present invention, heat conductive ceramic coating layers 61 and 62 are formed on either both sides or one side of the heat-dissipating sheet 60 used in both the attachable type module and the replaceable sheet type module, so that the additional effects such as moisture resistance, corrosion resistance, durability, heat resistance, solvent resistance, and the like can be improved is along with an increase in the heat-dissipating effect.

Moreover, in the present invention, the thin heat-dissipating sheet used in both the attachable type module and the replaceable sheet type module preferably uses one or more selected from thin metal sheets having an emissivity equal to or more than that of aluminum, copper, brass, sheet steel, stainless steel, and similar materials, which are excellent in heat conductivity. Also, in the case where the price of the materials, heat conductivity, and the like are taken into consideration, since the heat conductivity of copper is two times higher than that of aluminum as a result of comparison between prices of raw materials, it is most preferably to use the copper material.

Further, a ceramic coating layer 60 is formed on one side of the thin heat-dissipating sheet 60 used in both the attachable type module and the replaceable sheet type module through a surface treatment, and an opposite side of the heat-dissipating sheet 60, bonded to the EVA resin film is subjected to sanding treatment, gliding, and the like to change surface roughness depending on the materials to improve the bonding force between the heat-dissipating sheet and the EVA resin film, thereby further improving bondability.

That is, in the case where an adhesive for the heating-dissipating sheet is of a resin type, most preferably, the heating-dissipating sheet uses a metal material, which is bonded well to the resin.

In this case, the ceramic coating layer 62 formed only on one side of the heat-dissipating sheet is formed on a side opposite to the side of the heat-dissipating sheet, bonded to the EVA resin film.

For reference, a portion A of FIG. 6 and a portion C of FIG. 7 show that the ceramic coating layers 61 and 62 are formed on both sides of the heat-dissipating sheet 60. A portion B of FIG. 6 and a portion D of FIG. 7 show that the ceramic coating layer 62 is formed one side of the heat-dissipating sheet.

A ceramic coating method means that surface processing is performed on one side of the metal thin film of the heat-dissipating sheet or on one side of the polymeric resin to increase bondability and various kinds of ceramic materials are coated thereon. The ceramic coating method is generally known and is widely utilized in a ceramic processing field. Such a coating method has an advantage in that one surface is coated so that heat flows in one direction only. In the case where the ceramic coating method is applied to the photovoltaic module by utilizing this advantage, when the one surface is oriented toward the outermost side of the module, a heat-dissipating effect is attained through a flow path of the heat.

It is generally known that a ceramic coating material is not easily bonded to a metal thin film or a polymeric resin. Thus, the surface treatment is performed to coat such a ceramic coating material so that a ceramic coating product having a further excellent durability could be obtained and this surface treatment follows a general surface treatment technique.

In addition, the ceramic coating layers 61 and 62 are heat conductive ceramic coating films formed on the metal material surface of the heat-dissipating sheet, and are advantageous in that the thickness of the ceramic coating films can be adjusted to establish the optimal heat-dissipating conditions.

In the present invention, a heat-resistant ceramic material, which can be used in the ceramic coating layer, can include one or more selected from a metal ceramic material such as alumina, zirconia, titanium oxide, silica, and metal oxide, and a non-metallic ceramic material such as organic silane, inorganic silane, silane coupling agent, and CNT.

Moreover, the heat-resistant ceramic material basically uses only metal oxide. In the case where a non-metallic inorganic coating agent is partly mixed with the metal oxide at the time of coating the ceramic coating material, it is also possible to use a synthetic resin such as urethane or polyamide which can endure high temperature of 300° C. or so. A ceramic composition used in the present invention is not limited to only a composition having a specific component and component ratio, but may be controlled depending on the need of a manufacturer and the demand of a consumer.

The photovoltaic module according to the present invention preferably has the thickness of materials constituting the respective layers as follows: the glass substrate 10 has a thickness of from 1 to 5 mm; the front side solar EVA film 20 has a thickness of from 0.1 to 2 mm; the solar cells 30 have a thickness of from 0.15 to 0.3 mm; and the back side solar EVA film 40 has a thickness of from 0.1 to 2 mm. The thickness of each layer is always not limited to the predetermined thickness range, but may be controlled properly according the demand of a consumer or the need of a manufacturer.

In the present invention, the thickness of the ceramic coating layer formed on the outer surface of the heat-dissipating sheet 60 is set enough to increase the physical properties such as durability, corrosion resistance, moisture resistance, and the like of the heat-dissipating sheet. Preferably, the ceramic coating layer of the heat-dissipating sheet in the present invention is formed to a thickness of from 5 to 100 μm. The thickness of the ceramic coating layer is always not limited to the predetermined thickness range, but may be controlled properly according the need.

For reference, materials of the respective parts used in the photovoltaic module according to the present invention typically are the same as those used in the existing photovoltaic module. The respective parts constituting the photovoltaic module will be described below in brief.

In the present invention, preferably, a substrate allows sunlight to be incident on the solar cells 30 within the module, and a transparent or opaque reinforced glass substrate or a synthetic resin substrate is used as a plate to protect the solar cells 30. More preferably, the glass substrate is typically used.

In addition, the front side or back side solar EVA film 20 or 40 is an indispensable material for extending the lifespan of the photovoltaic module to 20 to 30 years. Also, the front side or back side solar EVA film 20 or 40 is positioned at the front or back side of the solar cells 30 and is a protecting layer made of a buffer material, which prevents the damage of the solar cells 30. In addition, the front side or back side solar EVA film 20 or 40 serves as an adhesive which bonds the glass substrate 10 and the back sheet 50. In the present invention, the solar EVA film 20 or 40 as the protecting layer is used in the form of a sheet, and the material thereof may use any one selected from the group consisting of EVA, EEA, fluorocarbon resin, and resin having a performance equal to or more than that of the above materials.

In addition, the solar cell 30 is a semiconductor device which performs a function of converting light into electricity, and has a minimum unit which is called a cell. Typically, voltage generated from one cell is 0.5 to 0.6V, which is very small, and thus a number of cells are serially connected to each other so that the cells are manufactured in the form of a panel to obtain a voltage of from a few V to several hundreds of V, which is called a module. A number of modules are connected to each other so that they are installed to conform to the purpose, which called an array.

Moreover, the back sheet 50 is disposed at a back side of the photovoltaic module and is a protecting layer which prevents moisture from infiltrating into the back side of the module to protect the solar cells 30 from the external environment. The back sheet 50 mainly uses a fluorocarbon resin.

The existing photovoltaic module composed of the above parts is manufactured such that the parts are laminated on top of each other, the laminated parts are vacuum-pressed by a laminator through a typical method, and an edge of the photovoltaic module is finished with aluminum by a typical method to sufficiently endure an external shock and have waterproof.

The construction of the present invention will be described hereinafter in more detail by way of examples and the present invention is not limited by the examples below.

1. Manufacture of Measurement Facility of the Heat-Dissipating Effect of Photovoltaic Module

As shown in a photograph of FIG. 8, a facility for measuring the heat-dissipating effect of the photovoltaic module was manufactured by the applicant's company. The measurement facility includes an acryl chamber in which two photovoltaic modules are installed, a surface-measuring thermometer for measuring the surface temperature of the acryl chamber, a chamber inside-measuring thermometer for measuring the internal temperature of the acryl chamber, and a sensor-attached thermometer for measuring the surface temperature of the two photovoltaic modules.

For reference, FIG. 8 is a photograph taken from the facility for measuring the heat-dissipating effect of the module.

The measurement facility of the heat-dissipating effect of the photovoltaic module as constructed above is a facility having the structure as shown in the photograph of FIG. 8. The measurement facility is constructed to simultaneously measure the amount of electricity generation, voltage, and current using the photovoltaic module efficiency measuring device and is designed to control the internal temperature thereof. The measurement facility used in the present invention is a surface temperature measuring facility of an experiment level.

2. Manufacture of Photovoltaic Module with Heat-Dissipating Function

### EXAMPLE 1

### Manufacture of Attachable Type Module

An attachable type module was manufactured in which the glass substrate 10, the front side solar EVA film 20, the solar cells 30, the back side solar EVA film 40, the back sheet 50, the pressure sensitive adhesive pressure-sensitive adhesive double-coated tape tape 55, and the heat-dissipating sheet 60 having the ceramic coating layer formed thereon are sequentially laminated in this order.

In addition, in the module according to Example 1, the thicknesses of the glass substrate 10, the front side solar EVA film 20, the solar cells 30, the back side solar EVA film 40, the back sheet 50, and the heat-dissipating sheet 60 were 2±0.1 mm, 1.5±0.1 mm, 0.2±0.05 mm, 1.5±0.1 mm, 0.3±0.1 mm, and 0.3±0.1 mm, respectively.

Besides, the heat-dissipating sheet used in the Example 1 is formed as an aluminum thin film, the material of the back sheet is fluorocarbon resin, the thicknesses of the ceramic coating layer formed on both sides of the heat-dissipating sheet is 20±10 μm.

Further, the ceramic coating layer of Example 1 is divided into the following three kinds of coating layers: a) a ceramic coating layer formed of a metal oxide such as alumina, titanium oxide, zirconia, and the like; b) a CNT coating layer; and c) an Si coating layer.

### EXAMPLE 2

### Manufacture of Replaceable Sheet Type Module

A replaceable sheet type module was manufactured in which the glass substrate 10, the front side solar EVA film 20, the solar cells 30, the back side solar EVA film 40, and the heat-dissipating sheet 60 having the ceramic coating layer formed thereon are sequentially laminated in this order.

Also, in the module according to the Example 2, the same conditions as those in the Example 1 were applied to the thicknesses of the glass substrate 10, the front side solar EVA film 20, the solar cell 30, the back side solar EVA film 40, and the heat-dissipating sheet 60.

In addition, the material of the heat-dissipating sheet and the back sheet used in Example 2 was the same as that in Example 1, and the same conditions as those in Example 1 were applied to the thicknesses and the kind of the ceramic coating layer formed on both sides of the heat-dissipating sheet.

### COMPARATIVE EXAMPLE 1

### Manufacture of Existing Module

A conventional photovoltaic module was manufactured which includes the glass substrate 10, the front side solar EVA film 20, the solar cells 30, the back side solar EVA film 40, and the heat-dissipating sheet 60, and was used as a control group for comparison with the Examples 1 and 2.

In addition, the thicknesses of the respective laminated materials in the module of Comparative Example 1 applied the same conditions as those of the limited thicknesses in the above Example 1. The material of the heat-dissipating sheet used in this Comparative Example 1 used an aluminum thin film which is not formed with a ceramic coating layer.

3. Heat-Dissipating Sheet Materials and Heat-Dissipating Effect by Surface Treatment

The surface temperatures of the heat-dissipating sheets 60 of the modules, applied to Examples 1 and 2 using the measurement facility of the heat-dissipating effect of the photovoltaic module as constructed above in Example 1 were respectively measured using ceramic-coated materials as listed in Table 1 below in daytime (nine to five) for each two clean days selected during the season time from March to April, and then the results of average values calculated by converting the heat-dissipating effect based on a relative temperature difference for a control group module are listed in Table 1 below.

TABLE 1

| | | Heat-dissipating effect | | |
|---|---|---|---|---|
| Ceramic | | Attach- | Replace- | |
| coating | | able type | able type | |
| method | Materials | module | module | Remarks |
| Ceramic | Aluminum thin | | | Evaluation on |
| coating | film | | | relative |
| (Al₂O₃, | Sheet steel | | | temperature |
| titanium | (CR material) | | | change for the |
| oxide) | Stainless | | | module having |
| | steel | | | heat-dissipating |
| | Copper plate | | | sheet whose |
| | Brass plate | | | surface is not |
| CNT coating | Aluminum thin | ◯ | ◯ | treated and the |
| | film | | | module not |
| | Sheet steel | Δ | ◯ | having heat- |
| | (CR material) | | | dissipating |
| | Stainless | Δ | ◯ | sheet |
| | steel | | | 1) Evaluation |
| | Copper plate | ◯ | ◯ | results |
| | Brass plate | ◯ | ◯ | Very good()- |
| Si coating | Aluminum thin | | | more than 15□ |
| | film | | | good(◯) - |
| | Sheet steel | ◯ | ◯ | from 10 to −14□ |
| | (CR material) | | | moderate(Δ) - |
| | Stainless | X | Δ | from 5 to −10□ |
| | steel | | | poor(x) - |
| | Copper plate | ◯ | ◯ | less than 5□ |
| | Brass plate | | | 2) Temperature |
| | | | | measurement |
| | | | | range |
| | | | | From room |
| | | | | temperature to |
| | | | | 90° C. |

As listed in Table 1 above, in the case where the aluminum thin film, the sheet steel, the stainless steel, and the copper plate, the brass plate as the materials of the heat-dissipating sheet were subjected to the ceramic coating, it was evaluated that the heat-dissipating effect is very good. In the case where the materials of the heat-dissipating sheet were subjected to the CNT coating, it was evaluated that the heat-dissipating effect is good or moderate. Also, in the case where the materials of the heat-dissipating sheet were subjected to the Si coating, it was evaluated that the heat-dissipating effect is poor in the attachable type module, but is moderate in the attachable type module. Thus, it was evaluated that the evaluated heat-dissipating sheets can be all used in the present invention.

4. Measurement of the Heat-Dissipating Effect of Photovoltaic Module

The conventional photovoltaic module having the limited structure of Comparative Example 1 was used as a control group module. Then, the surface temperatures of the photovoltaic modules of Examples 1 and 2 were respectively measured in daytime (nine to five) for each ten clean days selected during April, and then the results of average values calculated by converting the heat-dissipating effect based on a relative temperature difference for the control group module are listed in Table 2 below.

TABLE 2
(Unit: ° C.)

| | Examples | | Comparative | |
|---|---|---|---|---|
| Classification | 1 | 2 | example 1 | Remarks |
| a) Ceramic | From −13 | From −15 | From −10 | Module |
| coating | to −17 | to −20 | to −13 | reference |
| b) CNT coating | From −10 | From −13 | | temperature |
| | to −15 | to −15 | | From 20 |
| c) Si coating | From −10 | From −11 | | to 90° C. |
| | To −14 | to 15 | | |

In case of a) ceramic coating method, the ceramic coating was performed on a heat-dissipating sheet by a spray coating technique using a ceramic coating agent disclosed in Korean Patent Registration No. 10-0871877 issued to Thermolon Korea Co., Ltd, and the ceramic coated heat-dissipating sheet is subjected to heat treatment for 20-30 minutes at more than 80° C. to form a coating film on the heat-dissipating sheet. In case of b) CNT coating method, a CNT coating agent was mixed with an epoxy binder and then the mixture was coated on the heat-dissipating sheet by a spray coating technique due to absence of a self-adhesive force. 5-30% of CNT as an existing dispersed sample used in this experiment was coated on the heat-dissipating sheet and then dried at more than 80° C. to form a coating film on the heat-dissipating sheet. In case of c) Si coating method, an Si coating agent acting as a combined binder and coating agent was coated on the heat-dissipating sheet by the spray coating technique and then dried as an volatile solvent contained in the coating agent is vaporized. This Si coating method is excellent in utility because curing occurs even at low temperature, but is relatively low in fastness and durability as compared to the above two coating methods.

The results of Table 2 showed that the heat-dissipating effect obtained by the above methods a) to c) in Examples 1 and 2 are better than or partly equal to that in Comparative Example 1.

In addition, it can be seen that the replaceable type module of Example 2 in which the back sheet removed therefrom is replaced with the heat-dissipating sheet having the ceramic coating layer formed thereon exhibits a relatively high heat-dissipating effect as compared to the attachable type module of Example 1 in which the heat-dissipating sheet having the ceramic coating layer is attached to the outer surface of the back sheet using the pressure sensitive adhesive pressure-sensitive adhesive double-coated tape tape.

In other words, in case of the attachable type module of Example 1, the heat conductivity of the back sheet made of a fluorocarbon resin material is deteriorated. Thus, it could be found from the above examples that although the heat-dissipating sheet is attached to the outer surface of the back sheet, the ambient temperature of the attachable type module of Example 1 drops further to a maximum of 10° C. as compared to the replaceable type module of Example 2 in which the heat-dissipating sheet is directly attached to the back side solar EVA film 40.

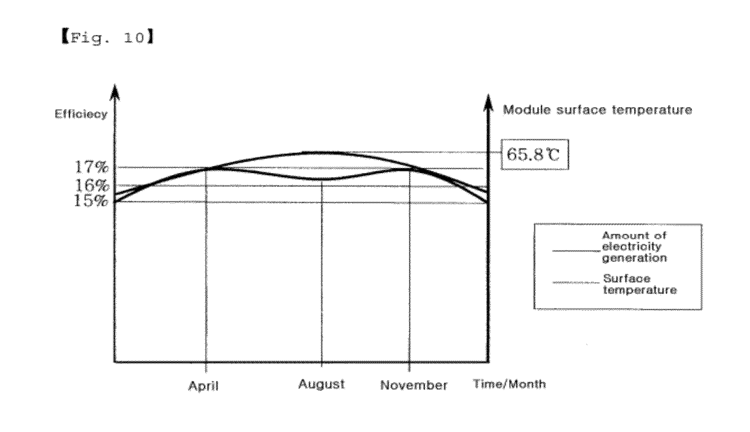

For reference, FIG. 9 is a graph illustrating the measured average values of changes in the surface temperature of a conventional photovoltaic module of Comparative Example 1 including a heat-dissipating sheet, an attachable type photovoltaic module of Example 1 to which the heat-dissipating sheet having the ceramic coating layer formed thereon is applied according to the present invention, and a replaceable type photovoltaic module of Example 2. It could be seen that the surface temperature of the conventional module attached with the heat-dissipating sheet of Comparative Example 1 is the highest, and the average values of the surface temperature of the module of the present invention are gradually decreased in the order of an Si coating layer, a CNT coating layer, and a ceramic coating layer.

5. Measurement of the Amount of Electricity Generation by Monthly Heat-Dissipating Effects of Photovoltaic Module

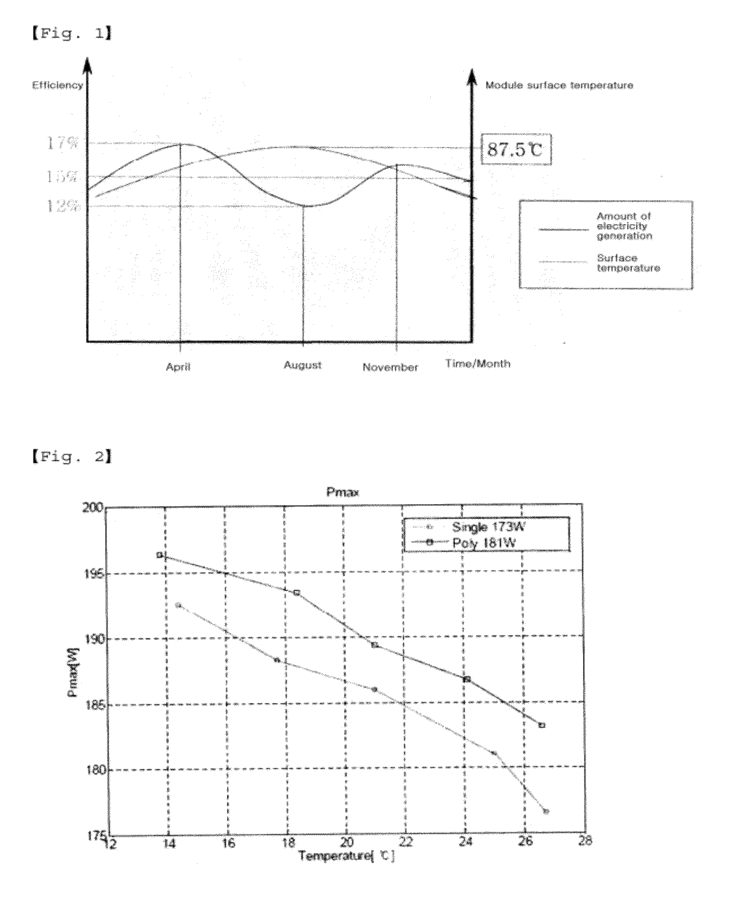

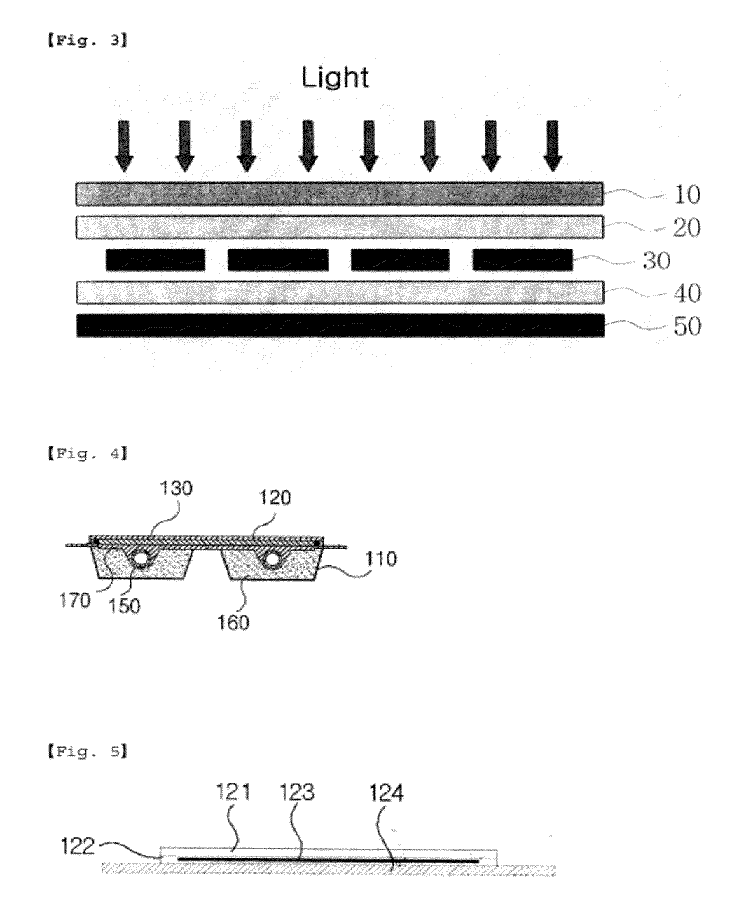

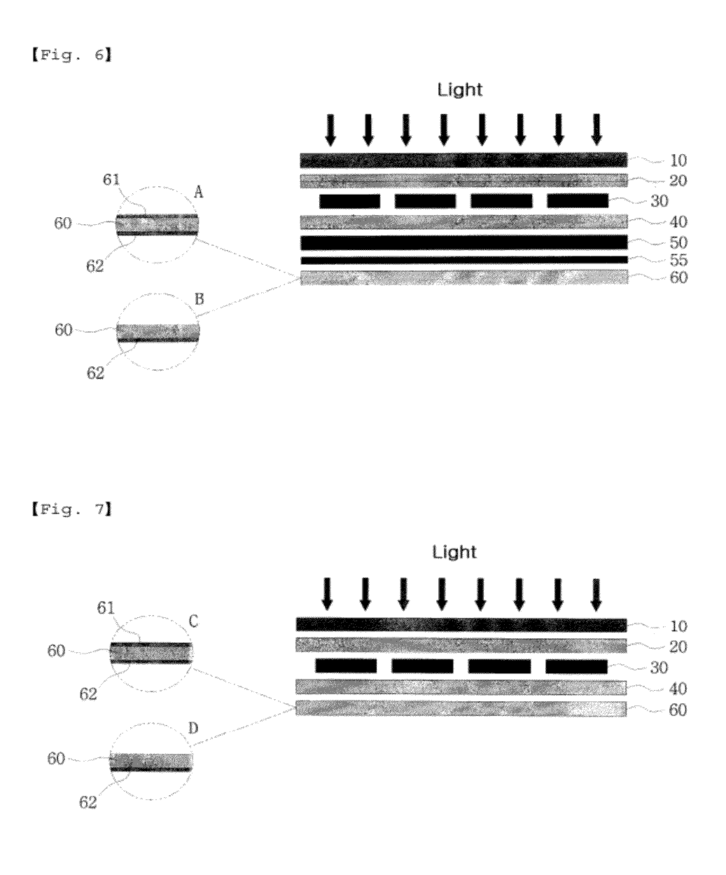

The measurement results of the amount of electricity generation by monthly heat-dissipating effects using the photovoltaic module of Example 2 according to the present invention are shown in the graph of FIG. 10. The measurement results of the amount of electricity generation by monthly heat-dissipating effects using the conventional photovoltaic module are shown in the graph of FIG. 1.

A result of comparison between the graph of FIG. 10 and the graph of FIG. 1 showed that the module of Example 2 is equal or superior to the conventional photovoltaic module in terms of the amount of electricity generated from solar in April and November when the ambient temperature is cool. Particularly, in August when the ambient temperature is high, the surface temperature of the conventional photovoltaic module reaches 87.5° C., and thus the efficiency of electricity generation from solar is no more than 12% as shown in the graph of FIG. 1. On the contrary, in case of the module of Example 2 employing the heat-dissipating sheet, it could be seen that the surface temperature of the module is no more than a maximum of 65.8° C. and the efficiency of electricity generation is increased to 16% as shown in the graph of FIG. 10.

Thus, it can be found in the above Examples that the amount of electricity generated from solar is greatly affected by the heat generated from the photovoltaic module and the peripheral device thereof.

FIG. 10 is a graph illustrating the efficiency of the amount of electricity generation according to the heat-dissipating effect of a photovoltaic module according to the present invention on a monthly basis.

While the present invention has been described in connection with the exemplary embodiments illustrated in the drawings, they are merely illustrative, and the invention is not limited to these embodiments. It is to be understood that various equivalent modifications and variations of the embodiments can be made by a person having an ordinary skill in the art without departing from the spirit and scope of the present invention. Therefore, the true technical scope of the present invention should be defined by the technical spirit of the appended claims.

### MODE FOR INVENTION

According to one aspect, the present invention is directed to a photovoltaic module including a heat-dissipating sheet having a ceramic coating layer, the module including a glass substrate 10, a front side solar EVA film 20, solar cells 30, a back side solar EVA film 40, and a back sheet 50, which are sequentially laminated in this order, wherein the heat-dissipating sheet 60 having the ceramic coating layer formed thereon is attached to the outer surface of the back sheet 50 using a pressure sensitive adhesive pressure-sensitive adhesive double-coated tape tape or adhesive 55.

According to another aspect, the present invention is directed to a photovoltaic module including a heat-dissipating sheet having a ceramic coating layer, the module including a glass substrate 10, a front side solar EVA film 20, solar cells 30, a back side solar EVA film 40, and the heat-dissipating sheet 60 having the ceramic coating layer formed thereon, which are sequentially laminated in this order.

### INDUSTRIAL APPLICABILITY

The photovoltaic module of the present invention implements a structure in which a heat-dissipating sheet formed with a ceramic coating layer is attached thereto through an improvement of an existing photovoltaic module. The inventive photovoltaic module has advantageous effects in that the ceramic coating layer is formed on a side opposite to a side of the heat-dissipating sheet abutting against the back sheet, so that a high thermal emissivity is obtained to maximize the amount and efficiency of electricity generation. In addition, since the photovoltaic module according to the present invention can be applied not only to new modules but also to modules which have already been produced and can be manufactured without changing the existing facility under the same process conditions as the existing process conditions, it is expected to be widely applied to various industrial fields.

1. A photovoltaic module including a heat-dissipating sheet having a ceramic coating layer, the module comprising a glass substrate 10, a front side solar EVA film 20, solar cells 30, a back side solar EVA film 40, and a back sheet 50, which are sequentially laminated in this order, wherein the heat-dissipating sheet 60 having the ceramic coating layer formed thereon is attached to the outer surface of the back sheet 50 using a pressure sensitive adhesive pressure-sensitive adhesive double-coated tape tape or adhesive 55.

2. A photovoltaic module including a heat-dissipating sheet having a ceramic coating layer, the module comprising a glass substrate 10, a front side solar EVA film 20, solar cells 30, a back side solar EVA film 40, and the heat-dissipating sheet 60 having the ceramic coating layer formed thereon, which are sequentially laminated in this order.

3. The photovoltaic module according to claim 2, wherein the heat-dissipating sheet 60 uses any one selected from thin metal sheets having an emissivity equal to or more than that of aluminum, copper, brass, sheet steel, stainless steel, and similar materials, which are excellent in heat conductivity.

4. The photovoltaic module according to claim 2, wherein the ceramic coating layer is formed on either one side or both sides of the heat-dissipating sheet.

5. (canceled)

6. The photovoltaic module according to claim 1, wherein the ceramic coating layer is formed on either one side or both sides of the heat-dissipating sheet.

7. The photovoltaic module according to claim 1, wherein the heat-dissipating sheet 60 uses any one selected from thin metal sheets having an emissivity equal to or more than that of aluminum, copper, brass, sheet steel, stainless steel, and similar materials, which are excellent in heat conductivity.

8. The photovoltaic module according to claim 7, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.

9. The photovoltaic module according to claim 6, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.

10. The photovoltaic module according to claim 4, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.

11. The photovoltaic module according to claim 3, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.

12. The photovoltaic module according to claim 2, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.

13. The photovoltaic module according to claim 1, wherein the ceramic coating layer uses at least one selected from a metal ceramic material such as alumina, zirconia, titanium oxide, silica, and metal oxide, and a non-metallic ceramic material such as organic silane, inorganic silane, silane coupling agent, and CNT.
